(19) United States
(12) Patent Application Publication
(10) Pub. No.: US 2019/0139830 A1
(43) Pub. Date: May 9, 2019

(54) SELF-ALIGNED GATE ISOLATION

(71) Applicant: GLOBALFOUNDRIES INC., GRAND CAYMAN (KY)

(72) Inventors: Ruilong XIE, Schenectady, NY (US); Minoli K. PATHIRANE, Albany, NY (US); Chanro PARK, Clifton Park, NY (US); Guillaume BOUCHE, Albany, NY (US); Nigel CAVE, Saratoga Springs, NY (US); Mahender KUMAR, San Jose, CA (US); Min Gyu SUNG, Latham, NY (US); Huang LIU, Mechanicville, NY (US); Hui ZANG, Guilderland, NY (US)

(73) Assignee: GLOBALFOUNDRIES INC., GRAND CAYMAN (KY)

(21) Appl. No.: 15/802,795

(22) Filed: Nov. 3, 2017

(51) Int. Cl. H01L 21/8234; H01L 27/092; H01L 27/088; H01L 29/06; H01L 21/768; H01L 21/311; H01L 21/02; H01L 29/78

(52) U.S. Cl. CPC H01L 21/823481; H01L 27/0924; H01L 27/0886; H01L 29/0649; H01L 29/785; H01L 21/76895; H01L 21/31116; H01L 21/02639; H01L 21/823431

(57) ABSTRACT

Fin field effect transistors (FinFETs) and their methods of manufacture include a self-aligned gate isolation layer. A method of forming the FinFETs includes the formation of sacrificial spacers over fin sidewalls, and the formation of an isolation layer between adjacent fins at self-aligned locations between the sacrificial spacers. An additional layer such as a sacrificial gate layer is formed over the isolation layer, and photolithography and etching techniques are used to cut, or segment, the additional layer to define a gate cut opening over the isolation layer. The gate cut opening is backfilled with a dielectric material, and the backfilled dielectric and the isolation layer cooperate to separate neighboring sacrificial gates and hence the later-formed functional gates associated with respective devices.

### BACKGROUND

The present application relates generally to semiconductor devices, and more specifically to methods for manufacturing fin field effect transistors.

Fully-depleted devices such as fin field effect transistors (FinFETs) are candidates to enable scaling of next generation gate lengths to 14 nm and below. Fin field effect transistors (FinFETs) present a three-dimensional architecture where the transistor channel is raised above the surface of a semiconductor substrate, rather than locating the channel at or just below the surface. With a raised channel, the gate can be wrapped around the sides of the channel, which provides improved electrostatic control of the device.

The manufacture of FinFETs typically leverages a self-aligned process to produce extremely thin fins, e.g., 20 nm wide or less, on the surface of a substrate using selective-etching techniques. A gate structure is then deposited to contact multiple surfaces of each fin to form a multi-gate architecture.

The gate structure may be formed using a gate-first or a gate-last fabrication process. A gate-last process, such as a replacement metal gate (RMG) process, utilizes a sacrificial or dummy gate, which is typically replaced by a functional gate after device activation, i.e., after epitaxial growth and/or dopant implantation into source/drain regions of the fins and an associated drive-in anneal, in order to avoid exposing the functional gate materials to the thermal budget associated with such processes.

Prior to removing the sacrificial gate and forming a functional gate, a gate cut module may be used to sever the sacrificial gate layer and form an opening within select regions of the architecture in order to isolate adjacent devices. In association with such a process, the sacrificial gate layer material removed from the openings is replaced with another, etch selective dielectric material. However, at advanced nodes, notwithstanding recent developments, it remains a challenge to define a gate cut opening with both the desired critical dimension(s) and alignment precision amidst a plurality of densely-arrayed fins.

### SUMMARY

Accordingly, it would be beneficial to provide a method for defining a sacrificial gate structure at critical dimensions with a high degree of accuracy and precision, especially a gate structure that enables formation of a functional replacement metal gate at advanced nodes without altering design rules or otherwise compromising real estate.

Disclosed is a gate cut scheme that may be used in conjunction with a replacement metal gate (RMG) process flow for manufacturing fin field effect transistors (FinFETs) where an isolation layer is self-aligned between adjacent fins to form a gate cut region. By fainting a self-aligned isolation layer, a gate cut region having desired critical dimensions and alignment can be formed independent of limitations associated with conventional photolithography.

In accordance with embodiments of the present application, a method of forming a semiconductor structure includes forming a plurality of semiconductor fins over a semiconductor substrate, forming a spacer layer over sidewalls of the plurality of semiconductor fins, forming an isolation layer at self-aligned locations between adjacent spacer layers, forming a second layer over the isolation layer and over the semiconductor fins, etching an opening in the second layer to expose a top surface of the isolation layer, and forming a dielectric layer within the opening.

An example semiconductor structure includes a plurality of semiconductor fins arranged over a semiconductor substrate, n isolation layer disposed over the substrate and between adjacent fins, and a dielectric layer disposed over the isolation layer, wherein a top surface of the isolation layer within a first region of the substrate is below a top surface of semiconductor fins adjacent to the isolation layer, and a top surface of the isolation layer within a second region of the substrate is above a top surface of semiconductor fins adjacent to the isolation layer.

### BRIEF DESCRIPTION OF SEVERAL VIEWS OF THE DRAWINGS

The following detailed description of specific embodiments of the present application can be best understood when read in conjunction with the following drawings, where like structure is indicated with like reference numerals and in which:

FIG. 1 is a schematic top down plan view of a FinFET device showing the location of a shared gate along line A and the location of a cut gate along line B;

FIG. 1A is a cross-sectional diagram along the dimension of the shared gate of FIG. 1 at an intermediate stage of fabrication according to various embodiments following a fin revealing etch and the formation of a spacer layer over sidewalls of the fins and over sidewalls of a fin hard mask disposed over the fins;

FIG. 1B is a cross-sectional diagram along the dimension of the cut gate of FIG. 1 at an intermediate stage of fabrication following a fin revealing etch and the formation of a spacer layer over sidewalls of the fins and over sidewalls of a fin hard mask disposed over the fins;

FIG. 2A shows the structure of FIG. 1A following the self-aligned deposition of an isolation layer between adjacent spacer layers and the recess etch of the isolation layer along the dimension of the shared gate according to various embodiments;

FIG. 2B shows the structure of FIG. 1B following the self-aligned deposition of an isolation layer between adjacent spacer layers and the formation of a sacrificial fill layer that prevents the recess etch of the isolation layer along the dimension of the cut gate;

FIG. 3A depicts the formation of a layer of amorphous silicon over an un-recessed isolation layer according to various embodiments and the formation of a gate hard mask over the layer of amorphous silicon;

FIG. 3B depicts the formation along the gate cut dimension of a layer of amorphous silicon over the isolation layer followed by the formation of a gate hard mask over the layer of amorphous silicon, as well as the etching of the gate hard mask and the layer of amorphous silicon to form a gate cut opening that is backfilled with a layer of etch selective dielectric material aligned with the isolation layer;

FIG. 4A shows selective removal of the amorphous silicon layer and etching of the isolation layer along the shared gate dimension according to further embodiments;

FIG. 4B shows removal of the amorphous silicon layer and retention of the backfilled etch selective dielectric material and the isolation layer between adjacent tins along the gate cut dimension;

FIG. 5A depicts a cross-sectional view along the shared gate dimension according to a further embodiment after the formation of a portion of a replacement metal gate (RMG) architecture including a high-k layer and a work function metal layer over the fins, and a sacrificial fill layer over the RMG architecture;

FIG. 5B depicts a cross-sectional view along the cut gate dimension according to a further embodiment after the formation of a portion of a replacement metal gate (RMG) architecture over the fins and a sacrificial fill layer over the RMG architecture, and the etching of the sacrificial fill layer to form a gate cut opening over the isolation layer that is backfilled with a layer of etch selective dielectric material;

FIG. 6A is a cross-sectional view along the shared gate dimension according to a still further embodiment after the formation of a replacement metal gate (RMG) over a plurality of fins;

FIG. 6B is a cross-sectional view along the gate cut dimension after the formation of a replacement metal gate (RMG) over a plurality of fins, and the etching of the replacement metal gate to form a gate cut opening over the isolation layer that is backfilled with a layer of etch selective dielectric material;

FIG. 7 shows the structure of FIG. 6B following the formation of a self-aligned capping layer over the replacement metal gate;

FIG. 8A is a cross-sectional view of a FinFET structure along a shared gate dimension following a fin reveal etch and removal of the fin hard mask, and the formation of a conformal oxide layer over exposed portions of the fins according to a further embodiment;

FIG. 8B is a cross-sectional view of a FinFET structure along a gate cut dimension following a fin reveal etch and removal of the fin hard mask, and the formation of a conformal oxide layer over exposed portions of the fins;

FIG. 9A shows the formation of a conformal layer of amorphous silicon over the structure of FIG. 8A, deposition and polishing of a dielectric fill layer over the layer of amorphous silicon, and the subsequent oxidation of exposed portions of the layer of amorphous silicon to form a silicon dioxide hard mask in situ;

FIG. 9B shows the formation of a conformal layer of amorphous silicon over the structure of FIG. 8B, deposition and polishing of a dielectric fill layer over the layer of amorphous silicon, and the subsequent oxidation of exposed portions of the layer of amorphous silicon to form a silicon dioxide hard mask in situ;

FIG. 10A shows selective removal of the dielectric fill layer from the structure of FIG. 9A to form a recess, an anisotropic etch back of the layer of amorphous silicon within the recess, and deposition and planarization of an isolation layer into self-aligned locations between adjacent fins;

FIG. 10B shows selective removal of the dielectric fill layer from the structure of FIG. 9B to form a recess, an anisotropic etch back of the layer of amorphous silicon within the recess, and deposition and planarization of an isolation layer into self-aligned locations between adjacent fins;

FIG. 11A depicts the formation of a layer of amorphous silicon over the isolation layer along the shared gate dimension and the formation of a gate hard mask over the layer of amorphous silicon;

FIG. 11B depicts the formation of a layer of amorphous silicon over the isolation layer along the gate cut dimension and the formation of a gate hard mask over the layer of amorphous silicon;

FIG. 12A is a cross-sectional view according to a further embodiment showing the post-fin reveal deposition of a conformal layer of amorphous silicon over the fins along the shared gate dimension;

FIG. 12B is a cross-sectional view according to a further embodiment showing the post-fin reveal deposition of a conformal layer of amorphous silicon over the fins along the gate cut dimension;

FIG. 12C is a cross-sectional view taken parallel to a fin length showing the post-fin reveal deposition of a sacrificial gate over a fin;

FIG. 13A shows the structure of FIG. 12A following etch back of the sacrificial gate, deposition and planarization of a self-aligned isolation layer between adjacent fins, and the deposition of a dielectric stack over the isolation layer;

FIG. 13B shows the structure of FIG. 12B following etch back of the sacrificial gate, deposition and planarization of a self-aligned isolation layer between adjacent fins, and the deposition of a dielectric stack over the isolation layer;

FIG. 13C is a cross-sectional view taken parallel to the length of a fin following deposition, patterning and etching of the dielectric stack to form a sacrificial gate;

FIG. 14A depicts the cross-sectional structure along the shared gate dimension after removal of a portion of the dielectric stack;

FIG. 14B depicts the cross-sectional structure along the gate cut dimension after removal of a portion of the dielectric stack;

FIG. 14C depicts the cross-sectional structure of FIG. 13C after the formation of sidewall spacers and epitaxial layers over source/drain regions of the fins, and a recess etch of the dielectric stack;

FIG. 15A depicts the cross-sectional structure along the shared gate dimension after removal of a portion of the dielectric stack;

FIG. 15B depicts the cross-sectional structure along the gate cut dimension after removal of a portion of the dielectric stack and subsequent etching of a dielectric layer from remaining portions of the dielectric stack to form a gate cut opening aligned with the isolation layer that is backfilled with a layer of etch selective dielectric material;

FIG. 15C shows the structure of FIG. 14C following the formation and planarization of a dielectric fill layer within the recess over each epitaxial layer;

FIG. 16A shows removal of the dielectric stack, and a recess etch of the isolation layer along the shared gate dimension,

FIG. 16B shows removal of the dielectric stack, and a recess etch of exposed portions of the isolation layer along the gate cut dimension,

FIG. 16C depicts removal of the dielectric stack, and a recess etch of exposed portions of the isolation layer,

FIG. 17A shows removal of the sacrificial gate and conformal oxide layers from over the fins, the formation of a RMG architecture, and the formation of a capping layer over the RMG architecture;

FIG. 17B shows removal of the sacrificial gate and conformal oxide layers from over the fins, the formation of a RMG architecture, and the formation of a self-aligned capping layer over the RMG architecture;

FIG. 17C shows removal of the conformal oxide layer from over the tin, the formation of a RMG architecture, and the formation and planarization of a self-aligned capping layer;

FIG. 18A shows the formation of a shared top source/drain contact over source/drain regions along a shared gate dimension of an exemplary FinFET structure according to various embodiments; and

FIG. 18B shows the formation of electrically isolated source/drain contacts over adjacent source/drain regions along a gate cut dimension of an exemplary FinFET structure according to various embodiments.

### DETAILED DESCRIPTION

Reference will now be made in greater detail to various embodiments of the subject matter of the present application, some embodiments of which are illustrated in the accompanying drawings. The same reference numerals will be used throughout the drawings to refer to the same or similar parts.

Disclosed are FinFET device structures and methods of manufacturing FinFET devices, and more particularly methods where the separation of adjacent devices includes the formation of sacrificial spacers over sidewalls of the fins, and the formation of an isolation layer between adjacent fins at self-aligned locations between the sacrificial spacers.

An additional layer such as a sacrificial gate layer is formed over the isolation layer, and photolithography and etching techniques are used to cut, or segment, the additional layer to define a gate opening over the isolation layer. According to various embodiments, the gate cut opening is backfilled with a dielectric material, such that the backfilled dielectric and the isolation layer cooperate to isolate neighboring sacrificial gates and hence the later-formed functional gates associated with respective devices. Independent transistors may be connected by local interconnection methods and/or back end of the line metallization layers to form integrated circuits, such as SRAM devices.

In various embodiments, a distance (d) between the sidewall of the self-aligned isolation layer and an adjacent fin may be less than 20 nm, e.g., 12, 14, 16 or 18 nm, including ranges between any of the foregoing values. Decreasing the distance (d) beneficially impacts the achievable density of devices. However, decreasing the distance (d) between adjacent structures may introduce design and processing challenges. As will be appreciated, such challenges may include the deposition of a functional gate stack, including a gate dielectric layer, gate conductor layer (e.g., work function metal layer) and conductive fill material within the available geometry, e.g., the space between the sidewall of the isolation layer and a neighboring fin. Using the presently-disclosed methods, a structure can be formed having a controlled and consistent distance (d) between the sidewall of an isolation layer and an adjacent fin without altering the design rules for the structure.

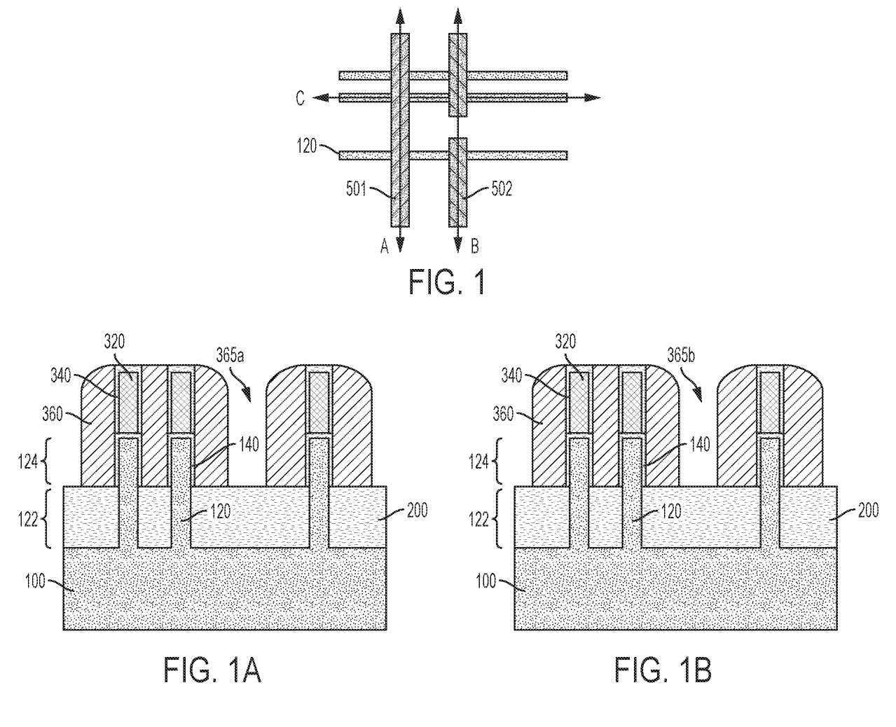

Referring to FIG. 1, a simplified schematic top down plan view of a FinFET device shows the location of a shared gate 501 along line A and the location of a segmented, or cut gate 502 along line B having a gate cut region located between adjacent fins 120. That is, a single shared gate 501 may traverse plural fins, while the cut gate 502 includes separate gates that may be used to form separate, independently controlled devices. Exemplary processes for forming the device structure of FIG. 1 are described herein with reference to FIGS. 1A-18B.

A cross-sectional diagram along the dimension of the shared gate of FIG. 1 (line A) is shown in FIG. 1A at an intermediate stage of fabrication following the post fin reveal formation of a plurality of fins 120 over a semiconductor substrate 100. A corresponding cross-sectional view along the dimension of the gate cut of FIG. 1 (line B) is shown in FIG. 1B.

Semiconductor substrate 100 may include a semiconductor material such as silicon, e.g., single crystal Si or polycrystalline Si, or a silicon-containing material. Silicon-containing materials include, but are not limited to, single crystal silicon germanium (SiGe), polycrystalline silicon germanium, silicon doped with carbon (Si:C), amorphous Si, as well as combinations and multi-layers thereof. As used herein, the term “single crystal” denotes a crystalline solid, in which the crystal lattice of the entire solid is substantially continuous and substantially unbroken to the edges of the solid with substantially no grain boundaries.

The substrate 100 is not limited to silicon-containing materials, however, as the substrate 100 may include other semiconductor materials, including Ge and compound semiconductors, including compound semiconductors such as GaAs, InAs, GaN, GaP, InSb, ZnSe, and ZnS, and II-VI compound semiconductors such as CdSe, CdS, CdTe, ZnSe, ZnS and ZnTe.

Substrate 100 may be a bulk substrate or a composite substrate such as a semiconductor-on-insulator (SOI) substrate that includes, from bottom to top, a handle portion, an isolation layer (e.g., buried oxide layer), and a semiconductor material layer.

Substrate 100 may have dimensions as typically used in the art and may include, for example, a semiconductor wafer. Example wafer diameters include, but are not limited to, 50, 100, 150, 200, 300 and 450 mm. The total substrate thickness may range from 250 microns to 1500 microns, although in particular embodiments the substrate thickness is in the range of 725 to 775 microns, which corresponds to thickness dimensions commonly used in silicon CMOS processing. The semiconductor substrate 100 may be a (100)-oriented silicon wafer or a (111)-oriented silicon wafer, for example.

As will be appreciated by those skilled in the art, the semiconductor fins 120 are arranged in parallel and are laterally isolated from each other within sub-fin region 122 by a shallow trench isolation layer 200. The fins 120 extend above shallow trench isolation layer (STI) layer 200 and form an active device region 124.

In various embodiments, fins 120 include a semiconductor material such as silicon, and may be formed by patterning and then etching the semiconductor substrate 100, e.g., a top portion of the semiconductor substrate. In several embodiments, the fins 120 are etched from, and therefore contiguous with the semiconductor substrate 100. For instance, fins 120 may be formed using a sidewall image transfer (SIT) process as known to those skilled in the art.

In certain embodiments, the fins 120 can have a width of 5 nm to 20 nm, a height of 40 nm to 150 nm, and a pitch of 20 nm to 100 nm, although other dimensions are also contemplated. Fins 120 may be arrayed on the substrate at a regular intrafin spacing or pitch. As used herein, the term “pitch” refers to the sum of the fin width and the spacing between neighboring fins. In example embodiments, the fin pitch may be within a range of 20 to 100 nm, e.g., 20, 30, 40, 50, 60, 70, 80, 90 or 100 nm, including ranges between any of the foregoing values, although smaller and larger pitch values may be used. In certain embodiments, plural fins may be arranged at a constant or variable pitch. For instance, first fins corresponding to a first device may be arranged at a first pitch, while second fins corresponding to a second device may be arranged at a second pitch.

As shown in the illustrated embodiment, portions of the fins 120 may be coated with a thin conformal oxide layer 140, which may be a sacrificial oxide layer or incorporated into a device having a thick gate dielectric layer. The conformal oxide layer 140 may include silicon dioxide, for example, and may be formed over the fins within the active device region 124 and over a fin hard mask. The conformal oxide layer 140 may have a thickness of 2 to 3 nm. During the course of manufacturing the FinFET device, the conformal oxide 140 may be stripped from source and drain regions of the fins and/or channel regions of the fins. By way of example, the revealed fin height, i.e., within active device region 124, may be 30 to 60 nm, e.g., 30, 40, 50 or 60 nm, including ranges between any of the foregoing values.

Shallow trench isolation (STI) layer 200 may be used to provide electrical isolation between the fins 120 and between adjacent devices as is needed for the circuit(s) being implemented. An STI process for FinFET devices involves creating isolation trenches in the semiconductor substrate 100 through an anisotropic etch process. The isolation trench between each adjacent fin may have a relatively high aspect ratio (e.g., ratio of the depth of the isolation trench to its width). A dielectric fill material, such as silicon dioxide, is deposited into the isolation trenches, for example, using an enhanced high aspect ratio process (eHARP) to fill the isolation trenches. The deposited dielectric material may then be polished by a chemical-mechanical polishing (CMP) process that removes the excess dielectric material and recess etched to create a planar STI structure having a uniform thickness.

“Planarization” and “planarize” as used herein refer to a material removal process that employs at least mechanical forces, such as frictional media, to produce a substantially two-dimensional surface. A planarization process may include chemical mechanical polishing (CMP) or grinding. Chemical mechanical polishing (CMP) is a material removal process that uses both chemical reactions and mechanical forces to remove material and planarize a surface.

In certain embodiments, the planarized STI oxide is etched back to form a recessed, uniformly thick oxide isolation layer 200 between the fins 120, where upper sidewalls of the fins 120 can be exposed for further processing.

Referring still to FIGS. 1A and 1B, fin caps, including a hard mask 320 and an overlying dielectric layer 340, are disposed over the fins. Hard mask 320 may include SiCO, SiCN, SiOCN, or silicon nitride, for example, and the overlying dielectric layer 340 may include silicon dioxide. As used herein, the compounds silicon nitride and silicon dioxide have compositions that are nominally represented as Si₃N₄ and SiO₂, respectively. The terms silicon nitride and silicon dioxide, refer to not only these stoichiometric compositions, hut also to nitride and oxide compositions that deviate from the stoichiometric compositions.

Sacrificial sidewall spacers 360 are formed over sidewalls of the fins 120 and over the fin caps, i.e., directly over the conformal oxide layer 140 and dielectric layer 340, using a conformal deposition process followed by an anisotropic etch. Amorphous elemental silicon (a-Si) can be deposited using atomic layer deposition (ALD) or chemical vapor deposition, such as low pressure chemical vapor deposition (LPCVD) at temperatures ranging from 450° C. to 700° C. Silane (SiH₄) can be used as the precursor for CVD silicon deposition. Adjacent sidewall spacers 360 define openings 365a, 365b between neighboring fins.

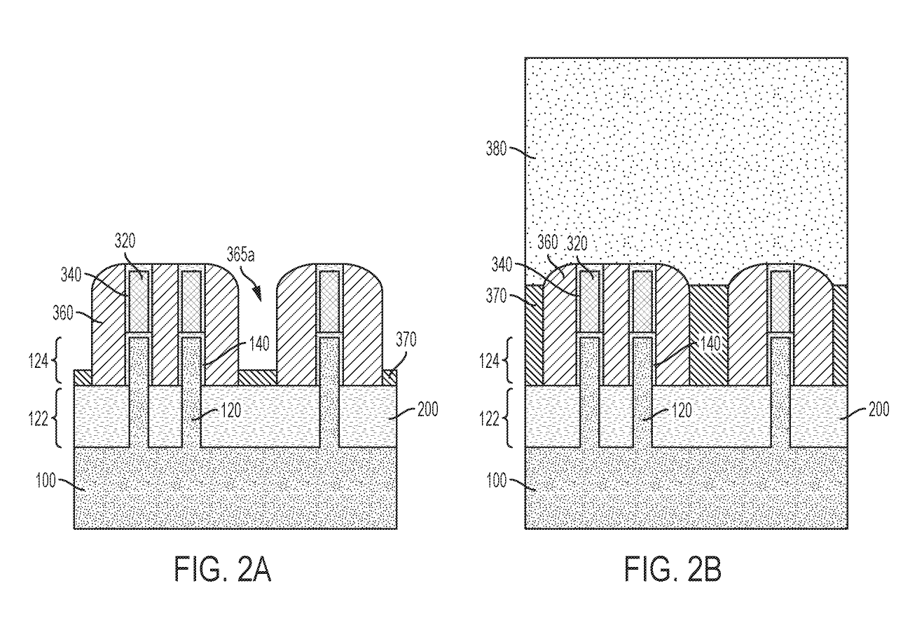

Referring to FIG. 2A and FIG. 2B, an isolation layer 370 is deposited within self-aligned locations within openings 365a, 365b. The isolation layer 370 extends along a length of the fins. The isolation layer 370 may include a dielectric material such as SiCO, SiCN, SiOCN, and the like. According to various embodiments, the isolation layer 370 and each of the sidewall spacers 360 and the hard mask 320 are formed from materials that can be etched selectively with respect to each other. The isolation layer 370 may be formed using a conformal deposition process, and in certain embodiments may pinch off between adjacent sidewall spacers 360. Deposition of the isolation layer may be followed by an etch back process effective to expose a top surface of the dielectric layer 340.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

The height of the self-aligned isolation layer 370 may be such that a top surface of the isolation layer 370 is initially above a top surface of the adjacent fins 120 but below a top surface of neighboring fin caps, e.g., below a top surface of hard mask 320. In certain embodiments, a height of the isolation layer 370 is less than twice a height of the fins within active device region 124, i.e., less than or equal to twice the height of the portion of the fins 120 that extend above STI 200. By way of example, a top surface of the as-formed self-aligned isolation layer 370 may be 10 to 50 nm above a top surface of a neighboring fin, e.g., 25 nm above the top surface of the neighboring fin.

In the illustrated embodiment, a sacrificial fill layer 380 may be formed over isolation layer 370 within the gate cut dimension (FIG. 2B), which prevents etching of the isolation layer 370 within the gate cut dimension, while the isolation layer 370 within the shared gate dimension (FIG. 2A) is at least partially removed. Although FIG. 2A shows a recess etch of the isolation layer 370, e.g., to a height less than the height of adjacent fins 120, it will be appreciated that etching may completely remove the isolation layer 370 from within the shared gate dimension. An exemplary sacrificial fill layer 380, may include an optical planarization layer (OPL) or a layer of amorphous carbon, for example.

A sacrificial fill layer 380 including amorphous carbon may be formed from a gas mixture including a hydrocarbon source and a diluent gas at a deposition temperature of 200° C. to 700° C. Optionally, an as-deposited amorphous carbon (a-C) layer may be cured such as by exposure to UV radiation at a curing temperature greater than 200° C.

Exemplary hydrocarbon compounds that may be included in the hydrocarbon source used to form the amorphous carbon layer may be described by the formula CₓH_{y}, where 1≤x≤10 and 2≤y≤30. Such hydrocarbon compounds may include, but are not limited to alkanes such as methane, ethane, propane, butane and its isomer isobutane, pentane and its isomers isopentane and neopentane, hexane and its isomers 2-methylpentane, 3-methylpentane, 2,3-dimethylbutane, 2,2-dimethyl butane, and the like; alkenes such as ethylene, propylene, butylene and its isomers, pentane and its isomers, and the like; dienes such as butadiene, isoprene, pentadiene and the like, and halogenated alkenes include monofluoroethylene, difluoroethylenes, trifluoroethylene, tetrachloroethylene, monochloroethylene, dichloroethylenes, trichloroethylene, tetrachloroethylene, and the like; and alkynes such as acetylene, propyne, butyne, vinylacetylene and derivatives thereof. Further hydrocarbon compounds include aromatic molecules such as benzene, styrene, toluene, xylene, ethylbenzene, acetophenone, methyl benzoate, phenyl acetate, phenol, cresol, furan, and the like, as well as halogenated aromatic compounds including monofluorobenzene, difluorobenzenes, tetrafluorobenzenes, hexafluorobenzenes and the like.

Suitable diluent gases may include, but are not limited to, hydrogen (H₂), helium (He), argon (Ar), ammonia (NH₃), carbon monoxide (CO), carbon dioxide (CO₂), and mixtures thereof.

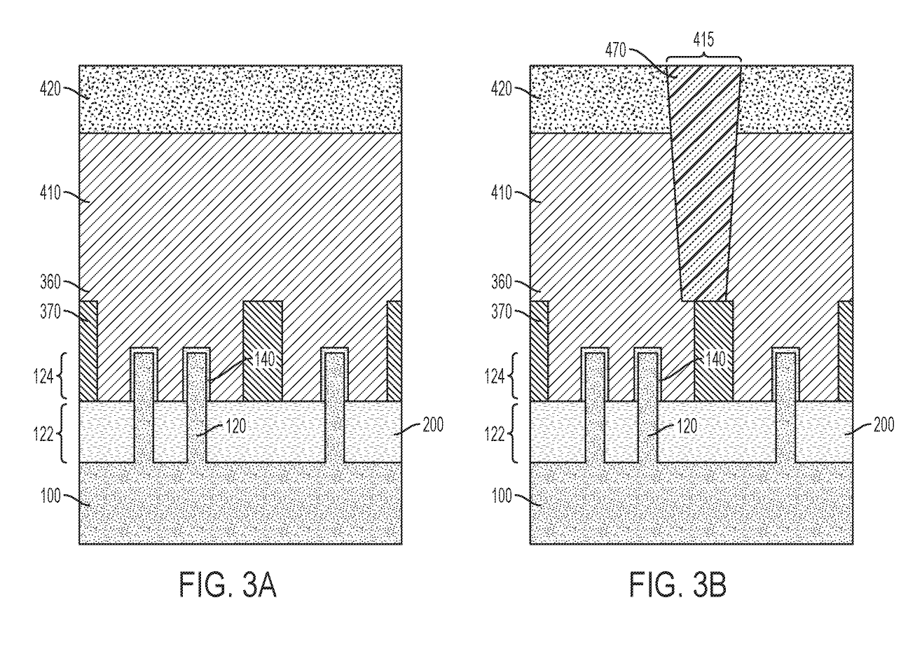

Continuing with reference to FIG. 3A and FIG. 3B, illustrated is an alternate embodiment to the structure described with reference to FIG. 2A and FIG. 2B. In the embodiments shown in FIGS. 3A and 3B, the recess etch of the isolation layer 370 along the shared gate dimension (FIG. 3A) is performed at a later stage of the manufacturing process, such that prior to the recess etch of the isolation layer 370 the hard mask 320 and the dielectric layer 340 overlying the top and sidewall surfaces of the hard mask 320 are removed, a layer of amorphous silicon 410 is formed over the isolation layer 370, a gate hard mask 420 is formed over the layer of amorphous silicon, and the amorphous silicon 410 and gate hard mask 420 are patterned to form a sacrificial gate. The gate hard mask 420 may, include silicon nitride, for example.

Referring to FIG. 3B, a gate cut opening 415 is formed within the gate hard mask 420 and extends through the amorphous silicon layer 410 to expose a top surface of the isolation layer 370 along the gate cut dimension. The gate cut opening 415 may be formed following the formation of gate, spacer, source/drain epitaxy and ILD formation.

Gate cut opening 415 may be formed using patterning and etching processes known to those skilled in the art. The patterning process may include photolithography, for example, which includes forming a layer of photoresist material (not shown) atop one or more layers to be patterned. The photoresist material may include a positive-tone photoresist composition, a negative-tone photoresist composition, or a hybrid-tone photoresist composition. A layer of photoresist material may be formed by a deposition process such as, for example, spin-on coating.

The deposited photoresist is then subjected to a pattern of irradiation, and the exposed photoresist material is developed utilizing a conventional resist developer. The pattern provided by the patterned photoresist material is thereafter transferred into the gate hard mask 420 and into the layer of amorphous silicon 410 layer utilizing at least one pattern transfer etching process.

According to various embodiments, in addition to a layer of photoresist, patterning and etching to form gate cut openings 415 may including forming a lithography stack (not shown) over the layer of amorphous silicon 410. A lithography stack may include one or more of an optical planarization layer, an etch stop layer, an amorphous carbon layer, an adhesion layer, an oxide layer, and a nitride layer. Such layers may be configured as known to those skilled in the art to provide a suitable masking layer to pattern and etch the underlying layer(s).

The pattern transfer etching process is typically an anisotropic etch. In certain embodiments, a dry etching process such as, for example, reactive ion etching (RIE) can be used. In other embodiments, a wet chemical etchant can be used. In still further embodiments, a combination of thy etching and wet etching can be used.

A gate cut opening 415 may have areal dimensions (length and width) that independently range from 15 to 40 nm, although lesser and greater dimensions may be used. According to various embodiments, the areal dimensions of the as-formed gate cut openings 415 are within lithography process windows for forming such structures, and enable the gate cut openings 415 to be defined with substantially vertical sidewalls. As used herein, “substantially vertical” sidewalls deviate from a direction normal to a major surface of the substrate by less than 5°, e.g., 0, 1, 2, 3, 4, or 5°, including ranges between any of the foregoing values. In certain embodiments, the width (w) of the gate cut opening 415 is less than 20 nm, e.g., 5, 10 or 15 nm.

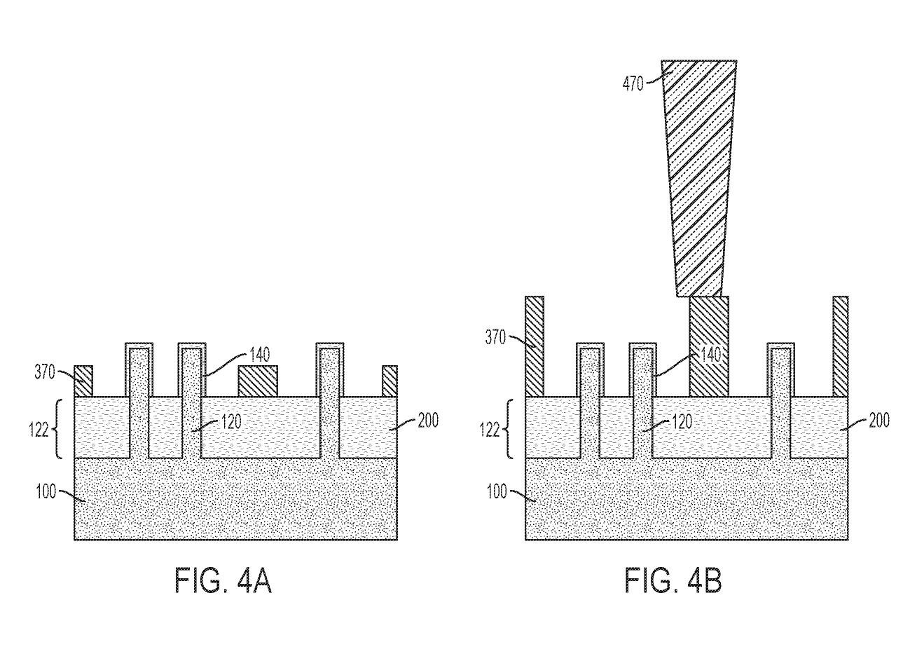

The gate cut opening 415 is then backfilled with a dielectric layer 470. Dielectric layer 470 may include silicon nitride. A CMP step may be used to planarize the structure. According to various embodiments, the dielectric layer 470 is formed from a material that is etch selective to both amorphous silicon and the gate hard mask, which referring to FIG. 4A and FIG. 4B, allows the amorphous silicon layer 410 to be removed during subsequent processing. In certain embodiments, isolation layer 370 and dielectric layer 470 include different materials. In certain embodiments, isolation layer 370 and dielectric layer 470 include the same material.

Referring in particular to FIG. 4A, the illustrated structure represents an alternative to the structure of FIG. 2A, whereby isolation layer 370 within the shared gate dimension may be recessed (or removed) during or subsequent to an etching process used to remove the amorphous silicon layer 410 (whereas in the process described in connection with FIG. 2A, the isolation layer 370 within the shared gate dimension is removed prior to forming the amorphous silicon layer 410 using a separate masking step). As seen with reference to FIGS. 4A and 4B, dielectric layer 470 may mask isolation layer 370 along the gate cut dimension (FIG. 4B) such that the isolation layer 370 along the gate cut dimension is substantially un-etched. In the embodiment illustrated in FIG. 4B, isolation layer 370 and dielectric layer 470 form a composite structure and cooperate to electrically separate later-formed functional gates located on either side of the layers 370, 470.

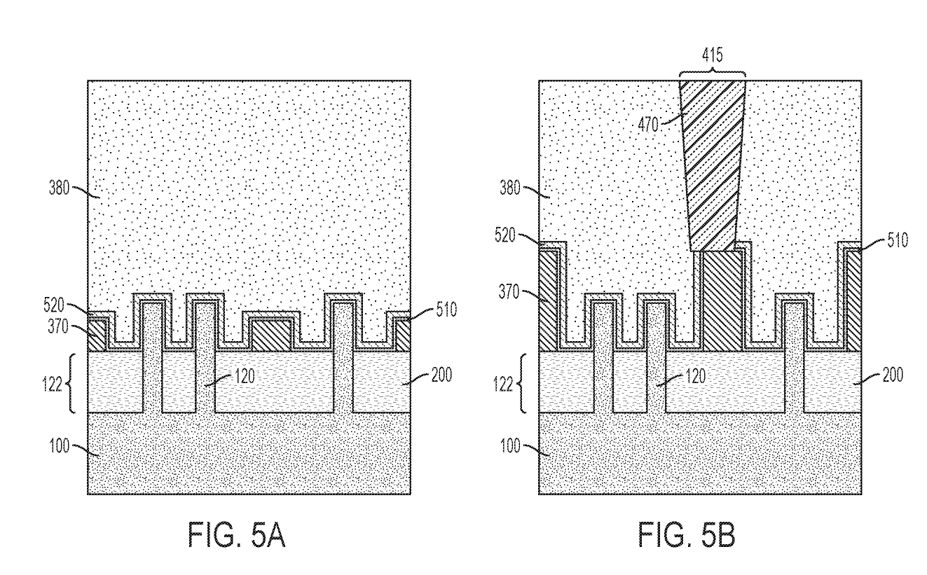

Referring to FIG. 5A and FIG. 5B, in accordance with a further embodiment, a gate cut module may be performed at a still later stage of the manufacturing process. In the illustrated embodiment, a portion of a replacement metal gate (RMG) architecture, including a high-k layer 510 and a work function metal layer 520, may be formed over the fins 120 and over isolation layer 370. The conformal oxide layer 140 may be removed from over the fins prior to depositing the high-k layer 510 and the work function metal layer 520. Then, a sacrificial fill layer 380, such as an organic planarization layer or a layer of amorphous carbon, is formed over the RMG layers, and in the gate cut dimension (FIG. 5B), a gate cut opening 415 is patterned and etched through the sacrificial fill layer 380 and through the RMG layers 510, 520 to expose a top surface of the isolation layer 370. The gate cut opening 415 is backfilled with a layer of etch selective dielectric material 470, which is deposited directly over the isolation layer 370. In the illustrated embodiment, within the shared gate dimension (FIG. 5A) a top surface of the isolation layer 370 is below a top surface of semiconductor fins adjacent to the isolation layer, while within the gat cut dimension (FIG. 5B) a top surface of the isolation layer 370 is above a top surface of semiconductor fins adjacent to the isolation layer. In certain embodiments, a width of the dielectric layer 470 may be greater than a width of the isolation layer 370.

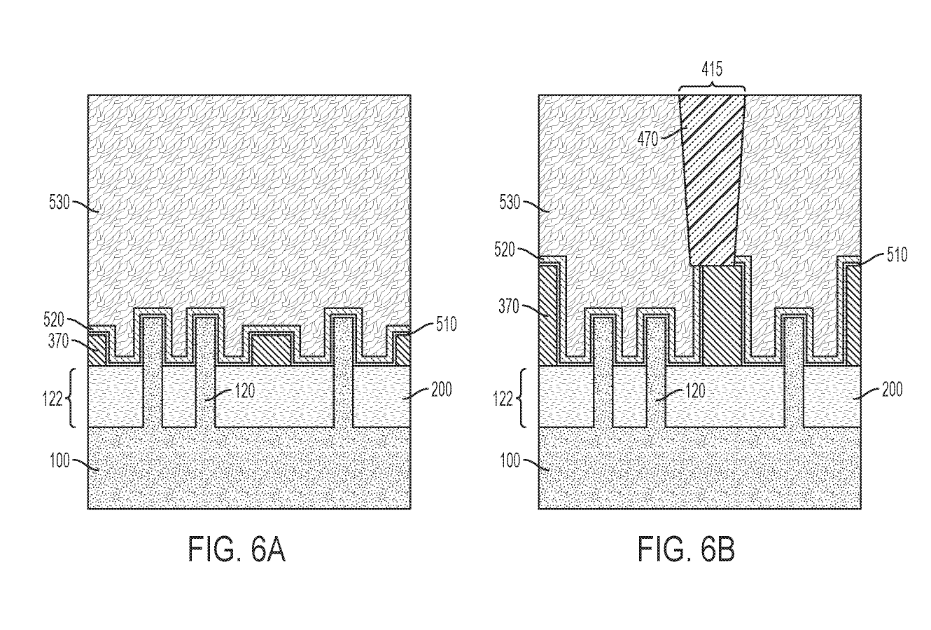

According to a further embodiment, with reference to FIG. 6A and FIG. 6B, a gate cut opening 415 can be etched and backfilled with an etch-selective dielectric layer after formation of the complete replacement metal gate, including a high-k layer 510, work function metal layer 520, and conductive fill layer 530.

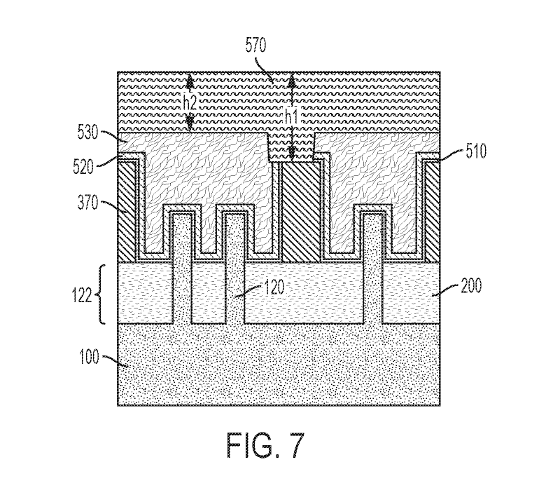

Shown in FIG. 7 is the structure of FIG. 6B after the formation and planarization of a self-aligned capping (SAC) layer 570 over the replacement metal gate. In the illustrated embodiment, following polishing of the SAC layer 570, a thickness (h1) of the SAC layer 570 overlying the isolation layer 370 may be greater than a thickness (h2) of the SAC layer 570 directly overlying the conductive fill layer 530.

As will be appreciated, in accordance with various embodiments described herein, etching to form the gate cut opening 415 need only extend through the sacrificial fill layer 380 (or conductive fill layer 530) to a top surface of the isolation layer 370, which is higher than a top surface of the adjacent fins 120. Compared to an alternative process where etching to form the gate cut opening 415 extends through the sacrificial fill layer 380 (or conductive fill layer 530) to STI 200, the relatively shallow etch depth results in a method and a resulting structure where the critical dimension of the opening 415 and the subsequent fill step each have a wide process window and are easy to control. For example, even in the example of a misaligned etch to form the gate cut opening 415, which may have a larger CD than the isolation layer 370, as shown schematically in FIGS. 3B, 5B and 6B, the isolation layer-to-fin spacing (d) (on each side of the isolation layer 370) is fixed by the self-aligned formation of the isolation layer 370, rather than by the critical dimension and alignment precision associated with photolithography.

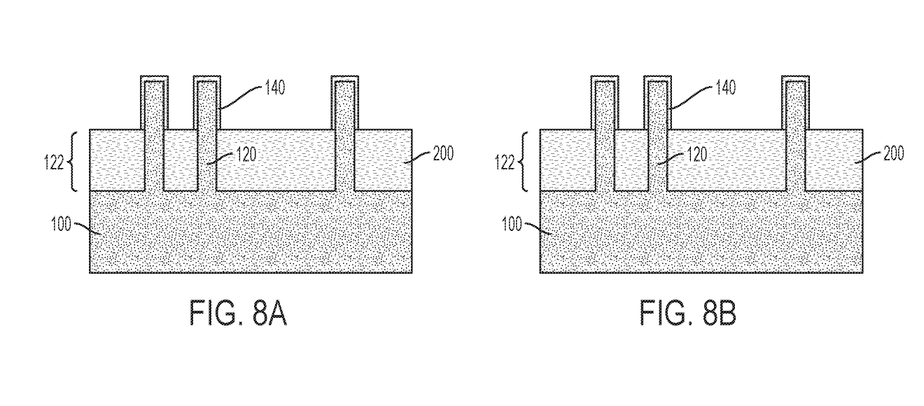

A further method for forming self-aligned gate isolation, as well as the resulting structure, are described with particular reference to FIGS. 8-11.

Referring to FIG. 8A, shown is a cross-sectional view of a FinFET structure along a shared gate dimension following a fin reveal etch and removal of the fin hard mask, and the formation of a conformal oxide layer 140 over exposed portions of the fins 120. A corresponding cross-sectional view along a gate cut dimension is shown in FIG. 8B.

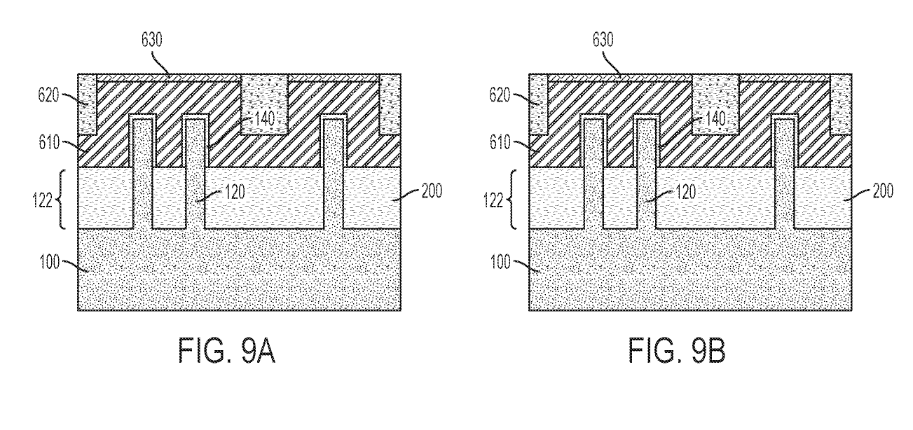

Referring to FIG. 9A and FIG. 9B, a conformal layer of amorphous silicon 610 is formed over the respective structures of FIGS. 8A and 8B as a sacrificial gate. The conformal layer of amorphous silicon 610 may have a thickness sufficient to completely cover the fins and the fin caps. For instance, a thickness of conformal layer of amorphous silicon 610 may range from 10 to 200 nm, e.g., 10, 15, 20, 50, 75, 100, 125, 150, 175 or 200 nm, including ranges between any of the foregoing values, although lesser and greater thicknesses may be used. Thereafter, a dielectric fill layer 620 is deposited over the layer of amorphous silicon and planarized. In various embodiments, the amorphous silicon layer 610 serves as a stopping layer for the planarization process, such that polishing of the dielectric fill layer 620 exposes a top surface of the amorphous silicon. Dielectric fill layer 620 may include CVD or ALD silicon nitride, for example. The layer of amorphous silicon 610 is then oxidized in situ to form a hard mask including a layer of silicon dioxide 630.

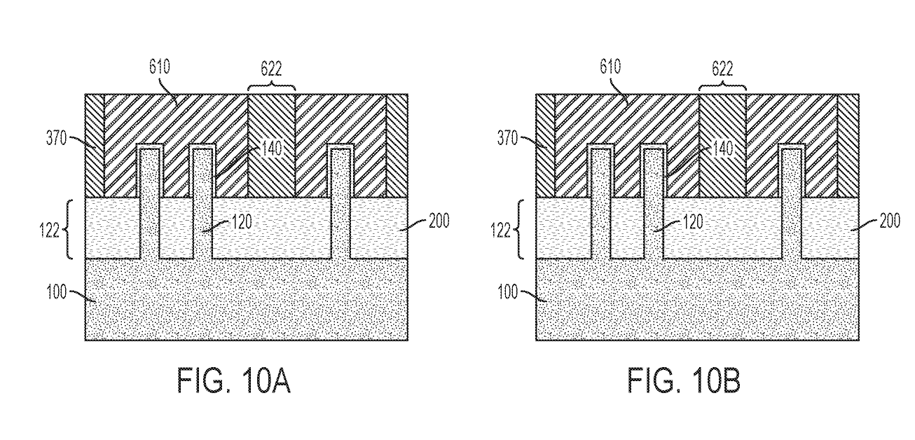

Referring to FIGS. 10A and 10B, the dielectric fill layer 620, which is used to template the in situ formation of hard mask 630, may be removed to form recess 622 using, for example, a wet etch that include hot phosphorous.

FIGS. 10A and 10B depict selective removal of the dielectric fill layer 620, followed by an anisotropic etch back of the amorphous silicon 610 within the recess 622 using hard mask 630 as an etch mask, and the deposition and planarization of a self-aligned isolation layer 370 within the recess 622 between adjacent tins. The isolation layer 370 is formed directly over STI layer 200, which is exposed at the bottom of the recess 622.

As shown in FIG. 10A and FIG. 10B, a chemical mechanical polishing step may be used to remove the overburden following deposition of the isolation layer 370 and produce a planarized structure. The sacrificial gate layer 610 may serve as a CMP etch stop during removal of the excess fill layer material.

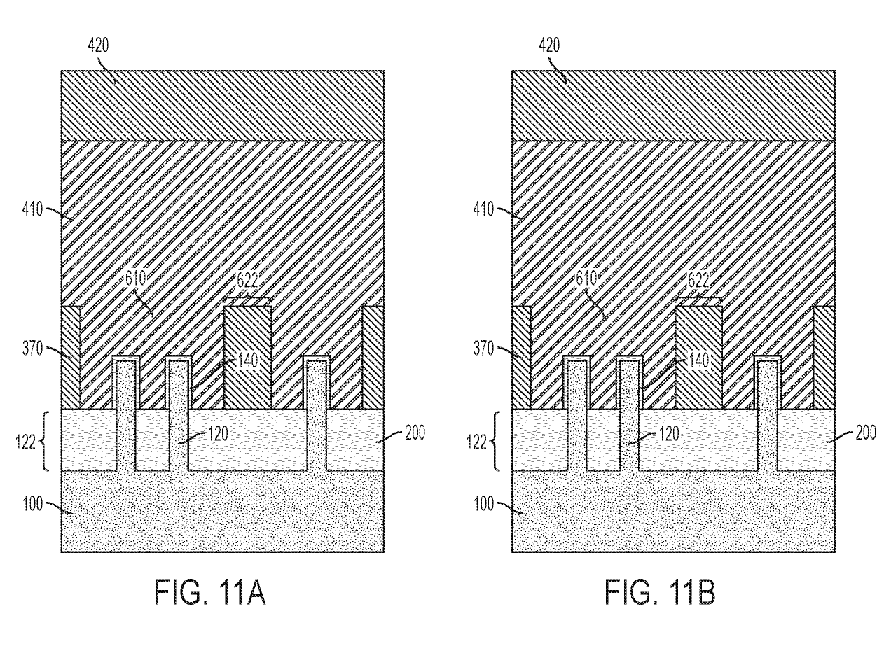

Referring to FIG. 114 and FIG. 11B, an additional layer of amorphous silicon 410 is formed over the conformal amorphous silicon layer 610 and over the isolation layer 370, and a gate hard mask 420 is formed over the additional layer of amorphous silicon 410. From the structure of FIGS. 11A and 11B, a gate cut opening (not shown) may be defined and backfilled with an etch selective dielectric layer to form a gate cut structure, as described above with reference to FIGS. 3A and 3B. In such a process, etching to form the gate cut opening extends through the amorphous silicon layer 410 to a top surface of the isolation layer 370 within the gate cut dimension.

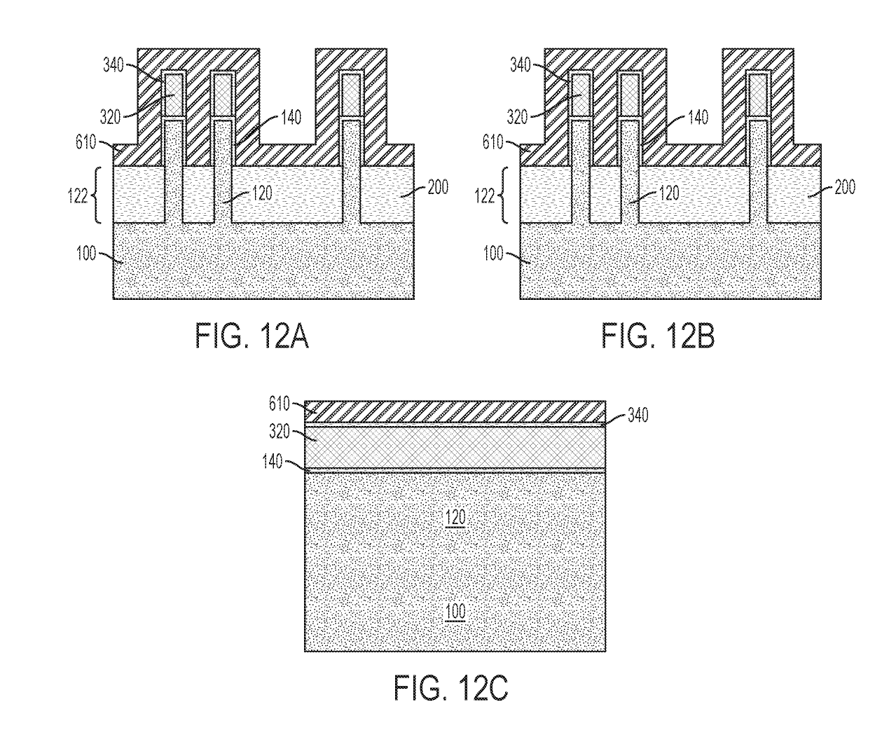

A further method for forming self-aligned gate isolation, as well as the resulting structure, is described with reference to FIGS. 12-18.

Referring to FIG. 12A and FIG. 12B, a conformal layer of amorphous silicon 610 is formed over fins 120 and over the fin caps, i.e., directly over the dielectric layer 340 as well as directly over conformal oxide layer 140. FIG. 12C is a cross-sectional view taken parallel to a fin length showing the post-fin reveal deposition of amorphous silicon layer 610 over fin 120.

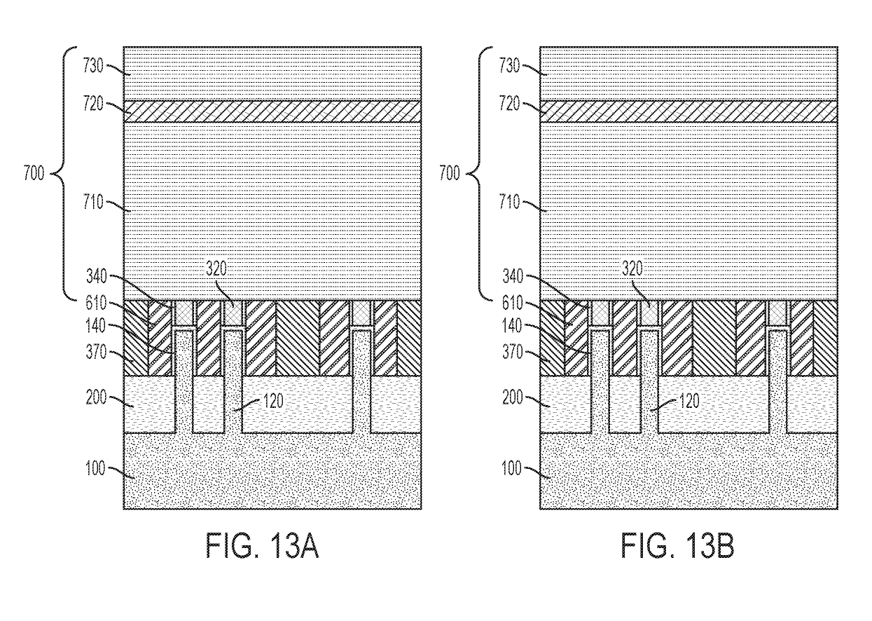

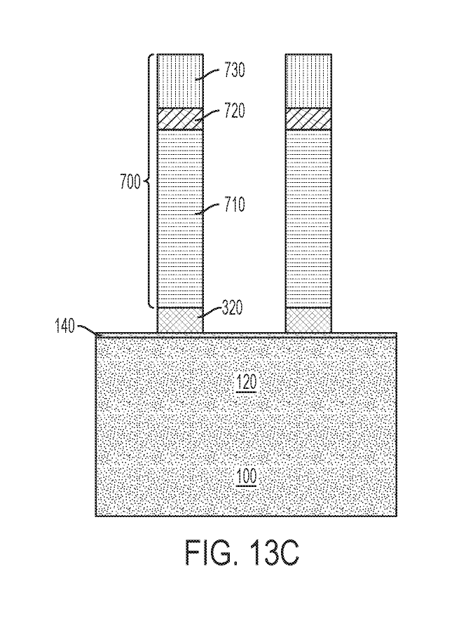

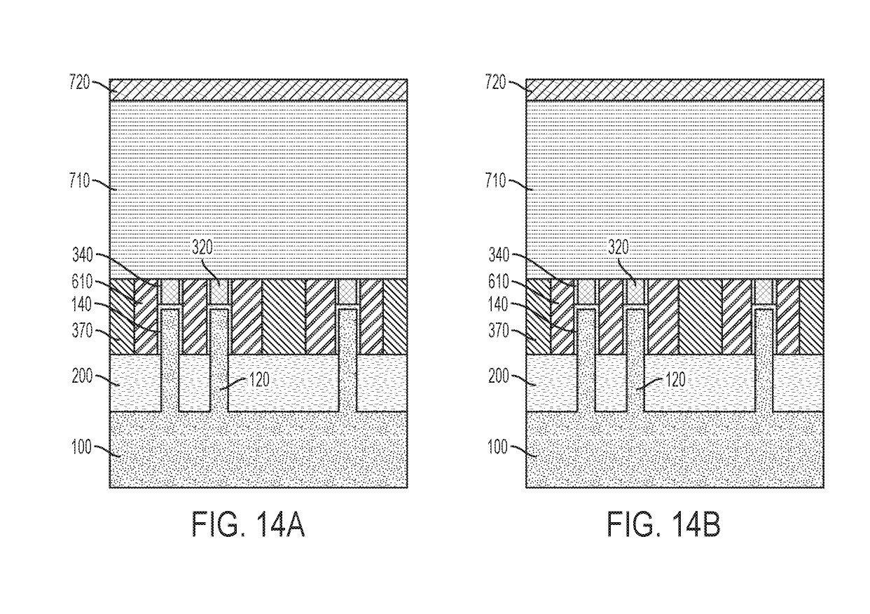

Referring to FIG. 13A and FIG. 13B, a recess etch of the layer of amorphous silicon 610 is used to expose a top surface of the fin caps as well as a top surface of STI 200. In various embodiments, the layer of amorphous silicon 610 is etched back such that a top surface of the layer of amorphous silicon 610 is below a top surface of the hard mask 320. Following the etch back, the layer of amorphous silicon 610 forms a spacer layer over a sidewall of a fin 120.

An isolation layer 370 is deposited within self-aligned locations directly over STI 200 between adjacent layers of the amorphous silicon sidewall spacers 610 and then polished to remove the overburden and form a planarized structure. Hard mask 320 may function as a CMP stopping layer during the polishing, such that dielectric layer 340 is removed from over the hard mask 320. As shown in FIGS. 13A-13C, a dielectric stack 700 including a first oxide layer 710, a nitride layer 720, and a second oxide layer 730 is then formed over the planarized surface. A further lithography and etching step is used to pattern the dielectric stack 700 into a sacrificial gate that overlies the fins 120 (FIG. 13C). The sacrificial gate overlies channel regions of the fins 120.

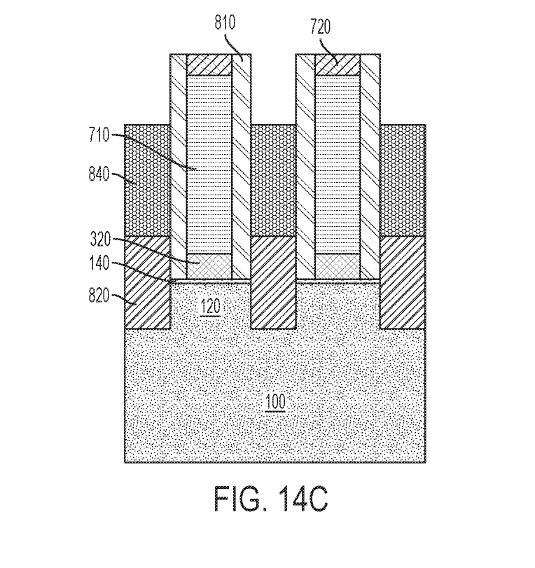

Referring to FIGS. 14A-14C, and in particular FIG. 14C, sidewall spacers 810 are formed over sidewalls of the dielectric stack 700 and over sidewalls of the underlying hard mask 320, i.e., in the illustrated embodiment, directly over conformal oxide layer 140. Sidewall spacers 810 may be formed by blanket deposition of a spacer material (e.g., using atomic layer deposition) followed by a directional etch such as reactive ion etching (RIE) to remove spacer material from horizontal surfaces. In certain embodiments, the sidewall spacer 810 thickness is 4 to 20 nm, e.g., 4, 10, 15 or 20 nm, including ranges between any of the foregoing values. Example sidewall spacer materials include silicon nitride and SiBCN.

As used here, “horizontal” refers to a general direction along a primary surface of a substrate, and “vertical” is a direction generally orthogonal thereto. Furthermore, “vertical” and “horizontal” are generally perpendicular directions relative to one another independent of orientation of the substrate in three-dimensional space.

Following removal of exposed portions of the conformal oxide layer 140 from over fins, source/drain regions 820 may be formed by ion implantation or selective epitaxy, e.g., using the sidewall spacers 810 as an alignment mask. According to exemplary embodiments, source/drain regions 820 may be formed by recessing semiconductor fins 120 followed by selective epitaxial growth from exposed portions of the fins.

As used herein, the terms “epitaxy,” “epitaxial” and/or “epitaxial growth and/or deposition” refer to the growth of a semiconductor material layer on a deposition surface of a semiconductor material, in which the semiconductor material layer being grown assumes the same crystalline habit as the semiconductor material of the deposition surface. For example, in an epitaxial deposition process, chemical reactants provided by source gases are controlled and the system parameters are set so that depositing atoms alight on the deposition surface and remain sufficiently mobile via surface diffusion to orient themselves according to the crystalline orientation of the atoms of the deposition surface. Therefore, an epitaxial semiconductor material has the same crystalline characteristics as the deposition surface on which it is formed. For example, an epitaxial semiconductor material deposited on a (100) crystal surface will take on a (100) orientation. Source/drain regions 820 may include silicon, silicon germanium, or another suitable semiconductor material.

The selective epitaxy process deposits an epitaxial layer directly onto the exposed surfaces of the fins 120 adjacent to the sidewall spacers 810. Exposed surfaces of the fins 120 may include the top surface as well as upper portions of the sidewalls of the tins proximate to the top surface. In various embodiments, a silicon epitaxial layer is formed without deposition of silicon on the exposed dielectric surfaces. Selective epitaxial layers may be formed using molecular beam epitaxy or chemical vapor deposition processes that are adapted for selective epitaxy.

An example silicon epitaxial process for forming top source (or drain) region(s) uses a gas mixture eluding H₂ and dichlorosilane (SiH₂Cl₂) at a deposition (e.g., substrate) temperature of 600-800° C. Other suitable gas sources for silicon epitaxy include silicon tetrachloride (SiCl₄), slime (SiH₄), trichlorosilane (SiHCl₃), and other hydrogen-reduced chlorosilanes (SiHₓCl₄₋ₓ).

An interlayer dielectric 840 is deposited directly over the epitaxial layers 820 to fill the openings between adjacent sidewall spacers 810. The interlayer dielectric 840 may include silicon dioxide and may be formed by chemical vapor deposition. The overburden may be removed by chemical mechanical polishing, e.g., using the nitride layer 720 as a CMP stop layer. As seen in FIGS. 14A and 14B, the CMP step may remove second oxide layer 730 from over nitride layer 720.

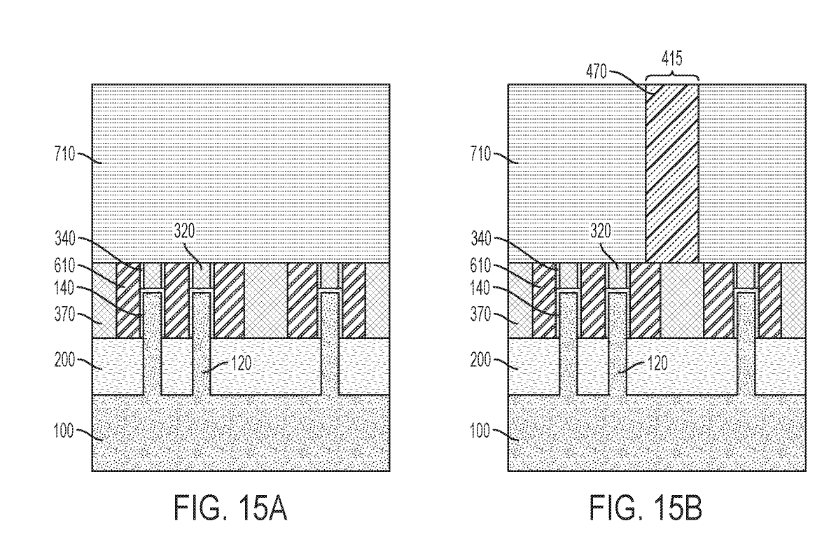

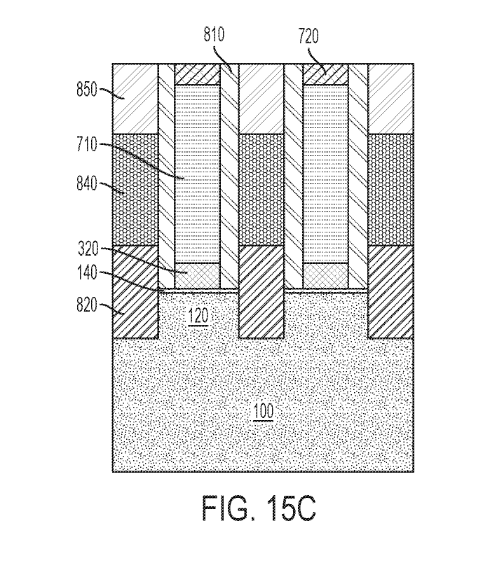

Prior to forming a gate cut opening, a selective etch may be used to recess the ILD layer 840, and the recessed regions may be filled with a nitride layer 850 (e.g., silicon nitride) and the structure again polished, as shown in FIG. 15C. Referring to FIGS. 15A-15C, according to various embodiments, a polishing step used to remove excess nitride layer 850 may stop on first oxide layer 710.

As shown in FIG. 15B, using conventional lithography and etching techniques, a gate cut opening 415 is formed within the first oxide layer 710 to expose a top surface of the isolation layer 370 along the gate cut dimension. As in previous embodiments, the gate cut opening 415 may be backfilled with a dielectric layer 470, and a CMP step may be used to planarize the structure.

Etching to form the gate cut opening 415 of FIG. 15B need only extend through the first oxide layer 710 to a top surface of the isolation layer 370. In contrast to a comparative process where etching to form the gate cut opening 415 would extend through the first oxide layer 710 to STI 200, the relatively shallow etch depth results in a method and a resulting structure where the critical dimension of the opening 415 and the subsequent fill step each have a wide process window and are easy to control. For example, even in the example of a misaligned etch to form the gate cut opening 415, as shown schematically in FIG. 15B, the isolation layer-to-fin spacing (d) (on each side of the isolation layer 370) is fixed by the self-aligned formation of the isolation layer 370, rather than by the alignment precision associated with photolithography.

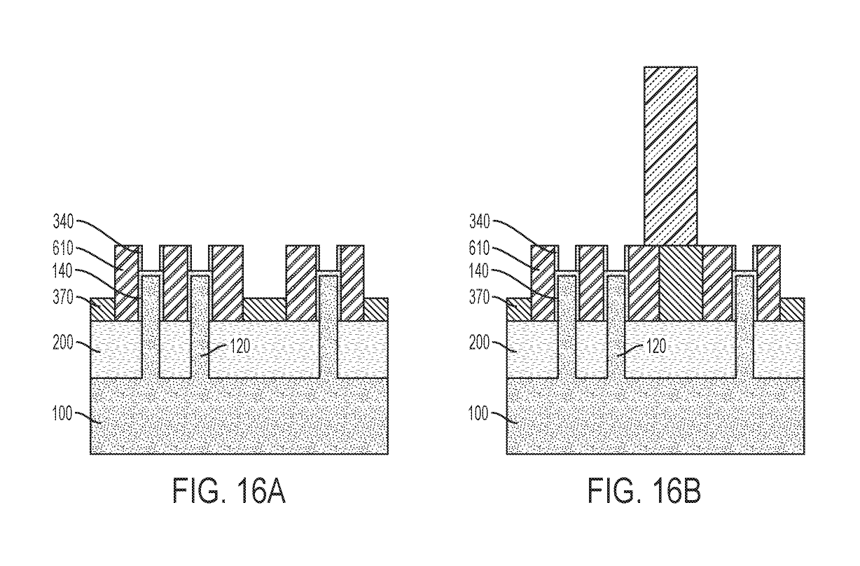

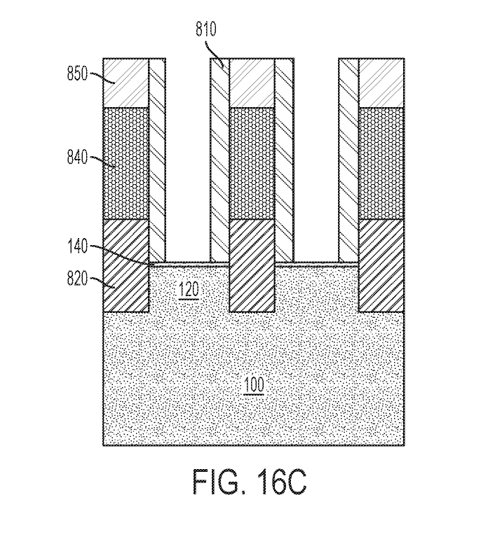

Referring to FIG. 16A, FIG. 16B and FIG. 16C, one or more etching processes can be used to remove the first oxide layer 710 and then recess exposed portions of the isolation layer 370. In various embodiments, first oxide layer 710 can be removed selectively with respect to a nitride dielectric layer 470, an amorphous silicon layer 610, and an SiCO isolation layer 370. As will be appreciated, the isolation layer 370 is recessed within the shared gate dimension (FIG. 16A) while within the gate cut dimension (FIG. 16B) dielectric layer 470 masks isolation layer 370 such that the isolation layer 370 along the gate cut dimension is substantially un-etched. Over channel regions of the fins 120, between the source/drain regions 820, removal of the first oxide layer 710 and etching of the gate hard mask 320 exposes a top surface of the conformal oxide layer 140 over the fins.

An isotropic wet etching process, such as a BHF-containing etch, can be used to etch the first oxide layer 710, followed by an anisotropic dry etch process to etch the gate hard mask 320 and the isolation layer 370. Alternatively, a wet chemical etchant can be used. In still further embodiments, a combination of dry etching and wet etching can be used.

The conformal oxide 140 may be removed along with remaining portions of the amorphous silicon layer 610. A replacement metal gate architecture 500, including a high-k layer, work function metal layer, and conductive fill metal (not separately shown) may be formed over the fins. The high-k layer and the work function metal layer may be deposited conformally, e.g., into the gaps between the isolation layer 370 and the neighboring fins 120. A recess etch of the conductive fill layer may be used to control its thickness.

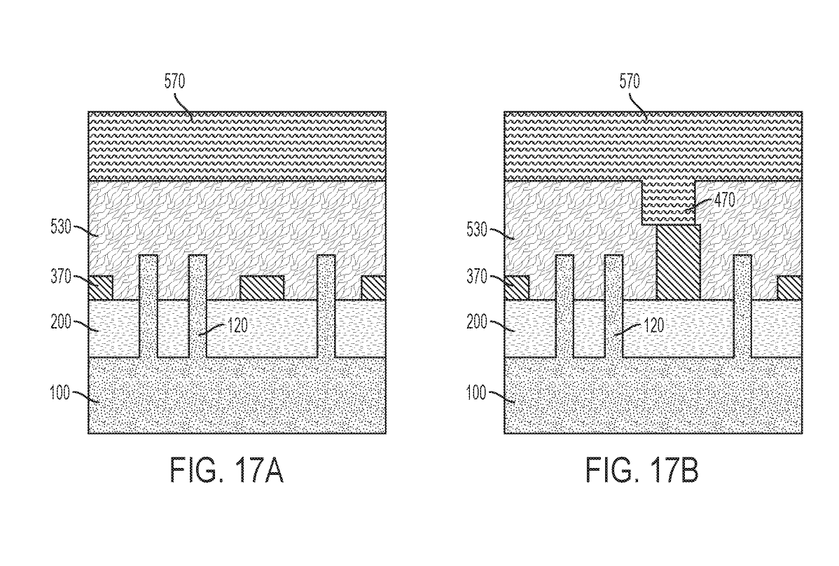

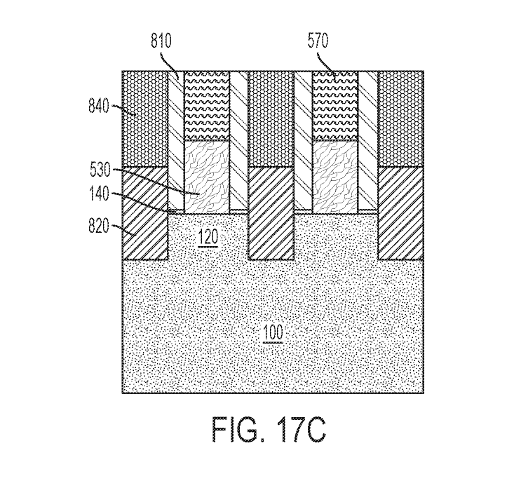

As will be appreciated, the conductive fill layer forms a shared gate along the shared gate dimension (FIG. 17A) while the isolation layer 370 and the dielectric layer 470 cooperate to electrically isolate first and second portions of the conductive fill layer along the gate cut dimension (FIG. 17B).

FIGS. 17A-17C depict removal of the dielectric stack 700, a recess etch of exposed portions of the isolation layer 370, removal of the sacrificial gate and conformal oxide layer from over the fin, the formation of a RMG architecture 500, and the formation and planarization of a self-aligned capping layer 570.

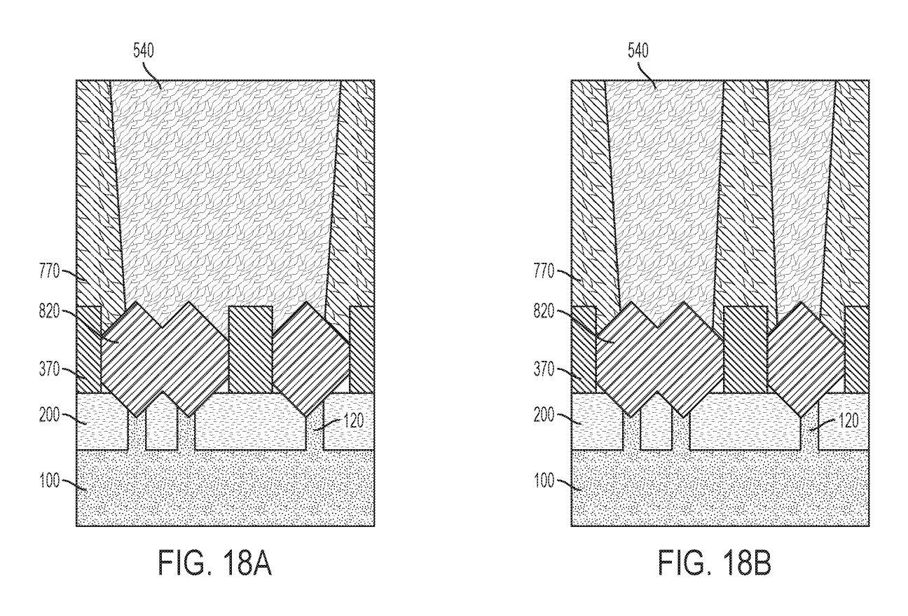

Referring to FIG. 18A and FIG. 18B, shown are exemplary cross-sectional structures through source/drain regions of fins 120, where a self-aligned isolation layer 370 is disposed between and provides electrical isolation for neighboring source/drain regions 820. In FIG. 18A, a shared source/drain contact 540 is formed directly over merged epitaxial source/drain regions 820. The source/drain contact 540 may include tungsten and may be formed using chemical vapor deposition into openings in ILD layer 770, which overlies the isolation layer 370. The ILD layer may include silicon dioxide.

FIG. 18A shows the formation of a shared top source/drain contact 540 extending through ILD layer 770 along a shared gate dimension of an exemplary FinFET structure, and FIG. 18B shows the formation of electrically isolated source/drain contacts 540 over adjacent source/drain regions 820 along a gate cut dimension of an exemplary FinFET structure. In various embodiments, self-aligned isolation layer 370 can prevent merger of neighboring source/drain regions 820 during the epitaxial growth thereof without blocking merger of the source/drain contact 540 across a shared source/drain.

As will be appreciated, the gate isolation methods and structures described herein leverage the formation of both a self-aligned isolation layer that provides precise alignment for the cut region of a sacrificial gate, and a lithographically-defined dielectric layer that overlies the isolation layer and together with the self-aligned isolation layer provides an effective gate isolation structure. By forming the isolation layer in a self-aligned manner between sacrificial sidewall spacers formed over the sidewalls of adjacent fins, both the desired critical dimension (CD) and alignment of the isolation layer can be achieved. The disclosed methods enable structures that are compatible with both single gate and shared gate devices.

According to various embodiments, the formation or deposition of a layer or structure, including the foregoing layers and structures, may involve one or more techniques suitable for the material or layer being deposited or the structure being formed. In addition to techniques or methods specifically mentioned, various techniques include, but are not limited to, chemical vapor deposition (CVD), low-pressure chemical vapor deposition (LPCVD), plasma enhanced chemical vapor deposition (PECVD), microwave plasma chemical vapor deposition (MPCVD), metal organic CVD (MOCVD), atomic layer deposition (ALD), molecular beam epitaxy (MBE), electroplating, electroless plating, ion beam deposition, spin-on coating, thermal oxidation, and physical vapor deposition (PVD) techniques such as sputtering or evaporation.

As used herein, the singular forms “a,” “an” and “the” include plural referents unless the context clearly dictates otherwise. Thus, for example, reference to a “layer” includes examples having two or more “layers” unless the context clearly indicates otherwise.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be understood that when an element such as a layer, region or substrate is referred to as being formed on, deposited on, or disposed “on” or “over” another element, it can be directly on the other element or intervening elements may also be present. In contrast, when an element is referred to as being “directly on” or “directly over” another element, no intervening elements are present.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a ferroelectric layer that comprises lead zirconate titanate include embodiments where a ferroelectric layer consists essentially of lead zirconate titanate and embodiments where a ferroelectric layer consists of lead zirconate titanate.

It will be apparent to those skilled in the art that various modifications and variations can be made to the present invention without departing from the spirit and scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A method of forming a semiconductor structure, comprising:
forming a plurality of semiconductor fins over a semiconductor substrate;
forming a spacer layer over sidewalls of the plurality of semiconductor fins;
forming an isolation layer at self-aligned locations between adjacent spacer layers;
forming a second layer over the isolation layer and over the semiconductor fins;
etching an opening in the second layer to expose a top surface of the isolation layer; and
forming a dielectric layer within the opening.

2. The method of claim 1, wherein the spacer layer comprises amorphous silicon.

3. The method of claim 1, wherein the isolation layer comprises a dielectric material selected from the group consisting of SiCO, SiCN and SiOCN.

4. The method of claim 1, further comprising etching the isolation layer, wherein a top surface of the etched isolation layer within a first region of the substrate is below a top surface of semiconductor fins adjacent to the isolation layer.

5. The method of claim 1, wherein a top surface of the isolation layer within a second region of the substrate is above a top surface of semiconductor fins adjacent to the isolation layer.

6. The method of claim 1, further comprising forming a shallow trench isolation layer over the semiconductor substrate between the semiconductor fins.

7. The method of claim 6, wherein the isolation layer is formed directly over the shallow trench isolation layer.

8. The method of claim 1, wherein the second layer comprises amorphous silicon.

9. The method of claim 1, wherein the second layer comprises a conductive layer.

10. The method of claim 1, wherein the second layer comprises a layer of amorphous carbon or an organic planarization layer (OPL) overlying a conductive layer.

11. The method of claim 1, wherein a width of the dielectric layer is greater than a width of the isolation layer.

12. The method of claim 1, further comprising forming a conductive layer over opposing sidewalls of the dielectric layer and the isolation layer.

13. A semiconductor structure, comprising:
a plurality of semiconductor fins arranged over a semiconductor substrate;
an isolation layer disposed over the substrate and between adjacent fins; and
a dielectric layer disposed over the isolation layer, wherein a top surface of the isolation layer within a first region of the substrate is below a top surface of semiconductor fins adjacent to the isolation layer, and a top surface of the isolation layer within a second region of the substrate is above a top surface of semiconductor fins adjacent to the isolation layer.

14. The semiconductor structure of claim 13, wherein the dielectric layer comprises silicon nitride and the isolation layer comprises a dielectric material selected from the group consisting of SiCO, SiCN and SiOCN.

15. The semiconductor structure of claim 13, further comprising a shallow trench isolation layer disposed over the semiconductor substrate between the semiconductor fins, wherein the isolation layer is disposed directly over the shallow trench isolation layer.

16. The semiconductor structure of claim 13, wherein a width of the dielectric layer is greater than a width of the isolation layer.

17. The semiconductor structure of claim 13, further comprising a first conductive layer disposed over first sidewalls of the dielectric layer and the isolation layer and a second conductive layer disposed over second sidewalls of the dielectric layer and the isolation layer.
